(19) United States
(12) Patent Application Publication
(10) Pub. No.: US 2022/0238323 A1
(43) Pub. Date: Jul. 28, 2022

(54) METHOD FOR SELECTIVE DEPOSITION OF DIELECTRIC ON DIELECTRIC

(71) Applicant: Tokyo Electron Limited, Tokyo (JP)

(72) Inventor: Robert Clark, Fremont, CA (US)

(21) Appl. No.: 17/161,033

(22) Filed: Jan. 28, 2021

(51) Int. Cl. H01L 21/02; H01L 21/768; C23C 16/40; C23C 16/06; C23C 16/455

(52) U.S. Cl. CPC H01L 21/022; H01L 21/02164; H01L 21/02178; H01L 21/02186; H01L 21/02216; H01L 21/0228; H01L 21/76831; H01L 21/02312; C23C 16/401; C23C 16/06; C23C 16/45529; H01L 21/7685; H01L 21/76897

(57) ABSTRACT

A method is described for an area selective deposition (ASD) process that is a dielectric on dielectric (DoD) ASD process performed over a major surface of a semiconductor substrate. The substrate comprises a conductive material embedded in a first dielectric layer, and the major surface comprises a conductive surface and a dielectric surface of the first dielectric layer. In this method, a metal-containing capping layer is formed selectively over the dielectric surface of the first dielectric layer. In a subsequent process step, a second dielectric layer is formed from the metal-containing capping layer. Hence, the DoD ASD process forms the second dielectric layer selectively over the dielectric surface of the first dielectric layer. The dielectric material for the second dielectric layer may be deposited by performing, for example, a catalytic decomposition of a precursor gas in a surface reaction where the catalyst is obtained from the selectively formed metal-containing layer.

### TECHNICAL FIELD

The present invention relates generally to a method for semiconductor processing, and, in particular embodiments, to a system and method for selective deposition of dielectric on dielectric.

### BACKGROUND

Generally, a semiconductor device, such as an integrated circuit (IC) is fabricated by sequentially depositing and patterning layers of dielectric, conductive, and semiconductor materials over a substrate to form a network of electronic components and interconnect elements (e.g., transistors, resistors, capacitors, metal lines, contacts, and vias) integrated in a monolithic structure. Process flows used to form the constituent structures of semiconductor devices often involve depositing and removing a variety of materials while a pattern of several materials may be exposed in a surface of the working substrate.

The minimum dimension of features in a patterned layer is shrunk periodically to roughly double the component density at each successive technology node, thereby reducing the cost per function. Innovations in patterning, such as immersion deep ultraviolet (i-DUV) lithography, multiple patterning, and 13.5 nm wavelength extreme ultraviolet (EUV) optical systems have brought some critical dimensions down close to ten nanometers. This squeezes the margin for pattern misalignment and puts pressure on process integration to provide self-aligned structures to prevent electrical opens and shorts in middle-of-line (MOL) and back-end-of-line (BEOL) interconnect elements. Innovative process flows for fabricating self-aligned structures may rely on availing highly selective etch and deposition processing techniques, thereby challenging semiconductor processing technology such as plasma enhanced deposition and etching to innovate and provide the requisite unit processes with the nanoscale precision, uniformity, and repeatability that IC manufacturing demands.

### SUMMARY

A method of processing a semiconductor substrate, the method includes having a substrate including a conductive material embedded in a first dielectric layer, the substrate having a major surface including a conductive surface of the conductive material and a dielectric surface of the first dielectric layer; capping the dielectric surface with a metal-containing layer by selectively depositing the metal-containing layer over the dielectric surface; and forming a second dielectric layer from the metal-containing layer, the second dielectric layer being selectively deposited over the first dielectric layer, the second dielectric layer having an upper exposed surface above the conductive surface after forming the second dielectric layer.

A method of semiconductor processing including: providing a substrate having a major surface including a pattern of conductive material embedded in a first dielectric layer; forming a self-assembled monolayer (SAM) selectively over the pattern of conductive material; forming a first layer including a first metal selectively over the first dielectric layer, the SAM including a tail group that blocks the forming of the first layer over the pattern of conductive material; and depositing a second dielectric layer selectively over the first dielectric layer by performing a catalytic process using the first layer over the first dielectric layer.

A method of semiconductor processing, the method including: having a substrate including a conductive material embedded in a first dielectric layer, the substrate having a major surface including a conductive surface of the conductive material and a dielectric surface of the first dielectric layer; performing a plurality of cycles of a cyclic deposition process to form a second dielectric layer selectively over the first dielectric layer, each cycle of the cyclic deposition process including: selectively covering the conductive surface with a self-assembled monolayer (SAM); forming a first layer including a first metal selectively over the dielectric surface, the SAM including a tail group that blocks the forming of the first layer on the conductive surface; depositing a portion of the second dielectric layer selectively over the dielectric surface by performing a catalytic process using the first layer, the deposited portion of the second dielectric having an exposed dielectric surface above the conductive surface; and removing the SAM to expose the conductive surface.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1A illustrates a flow diagram for a method for selective deposition of dielectric on dielectric, in accordance with an embodiment;

FIG. 1B illustrates a flow diagram for a method for selective deposition of dielectric on dielectric, in accordance with an embodiment;

FIG. 2 illustrates a cross-sectional view of a substrate with a schematic of a self-assembled monolayer (SAM) formed selectively on a surface of the substrate, in accordance with an embodiment;

FIGS. 3A-3G illustrate cross-sectional views of a semiconductor device at various intermediate process steps in a process flow implementing a selective deposition process forming a dielectric on dielectric layer, in accordance with an embodiment;

FIGS. 4A-4G illustrate the respective planar views of a top surface of the substrate illustrated in cross-sectional views in FIGS. 3A-3G;

FIGS. 5A-5J illustrate cross-sectional views of a semiconductor device at various intermediate stages of fabrication in a process flow forming a self-aligned feature utilizing the selectively deposited dielectric on dielectric layer illustrated in FIGS. 3A-3G and 4A-4G, in accordance with an embodiment;

FIGS. 6A-6J illustrate the respective planar views of a top surface of the substrate illustrated in cross-sectional views in FIGS. 5A-5J;

FIGS. 7A-7B illustrate cross-sectional views of a fully-self aligned via (FSAV) incorporating the self-aligned feature formed with the process flow illustrated in FIGS. 6A-6J, in accordance with an embodiment;

FIGS. 8A-8B illustrate the respective planar views of a top surface of the substrate illustrated in cross-sectional views in FIGS. 7A-7B; and

FIG. 9 illustrates a flow diagram for a method for selective deposition of dielectric on dielectric implemented as a cyclic deposition process, in accordance with an embodiment.

### DETAILED DESCRIPTION OF ILLUSTRATIVE EMBODIMENTS

This disclosure describes a method for selective deposition of dielectric on dielectric (DoD). In various embodiments, a self-aligned pattern of a dielectric is formed by selectively depositing a second dielectric layer over the surface of a patterned first dielectric layer. The first dielectric layer may be inlaid with a pattern of conductive interconnect elements, thereby providing a top major surface having a conductive region and a dielectric region. Embodiments of the selective DoD deposition process may provide the advantages of high selectivity and improved process yield with a low density of defects. The selective DoD deposition process is described in the context of an example BEOL process flow for forming a fully self-aligned via in a multilevel interconnect system of a semiconductor integrated circuit. However, the selective DoD deposition process may be applied to other steps of the process flow in other structures, as known to a person skilled in the art.

As known to persons skilled in the art, a multilevel interconnect system may be fabricated by forming a stack of interconnect levels, each interconnect level comprising a dielectric layer having inlays of a pattern of conductive lines forming a lateral network, and a pattern of vertical conductive vias. The vias connect the pattern of conductive lines to a vertically adjacent pattern of conductive lines in the interconnect level below. A commonly used method for fabricating an interconnect level is the dual damascene method. The dual damascene method comprises depositing an interlayer dielectric (ILD) layer, patterning openings in the ILD layer, depositing metal to fill the openings, and removing the excess metal from over the top of the ILD layer using a chemical mechanical planarization (CMP) process. By removing the excess metal, the CMP step exposes the ILD layer, thereby forming a planarized top surface comprising a dielectric surface and a conductive surface. The ILD layer comprises low dielectric constant (low-K) dielectric layers and may also include one or more etch stop layers. Two patterning steps are performed to form openings in the ILD layer prior to depositing metal. One patterning step forms trenches in a top portion of the ILD layer for the conductive lines. The other patterning step forms holes extending further through the ILD layer to be used subsequently to form the conductive vias that connect the pattern of conductive lines of the upper interconnect level to the pattern of conductive lines of the lower interconnect level disposed below the ILD layer.

The example BEOL process flow adopts a trench-first integration approach where the trenches are patterned first. The via holes are then patterned self-aligned to the trenches, as explained in further detail below. A via structure is said to be fully self-aligned if, in addition, the via holes are formed self-aligned to the pattern of conductive lines of the adjacent lower interconnect level below the ILD layer. One method of forming a fully self-aligned via (FSAV) starts with an incoming substrate, where the top surface of the incoming substrate is the planarized surface of the lower interconnect level. The surface is then modified by executing a process flow that includes performing a selective DoD deposition over the ILD layer of the lower interconnect level. In this disclosure, an example FSAV process flow incorporating an embodiment of the selective DoD deposition process will be described.

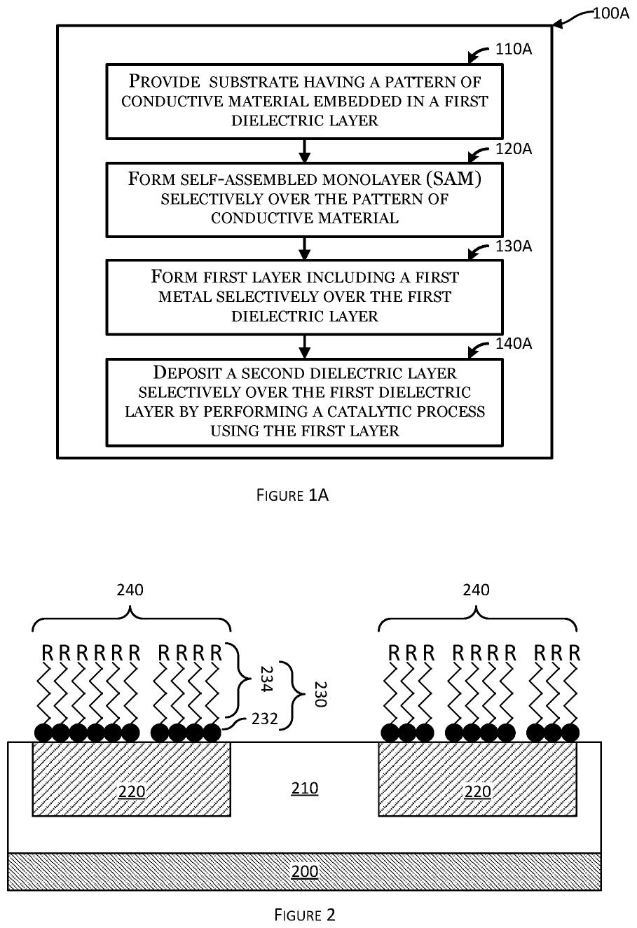

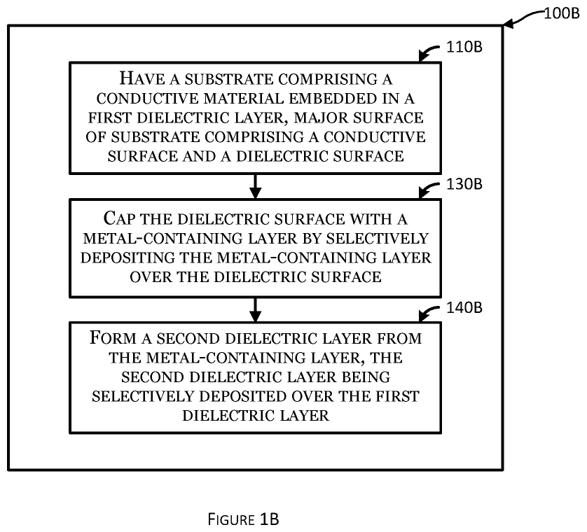

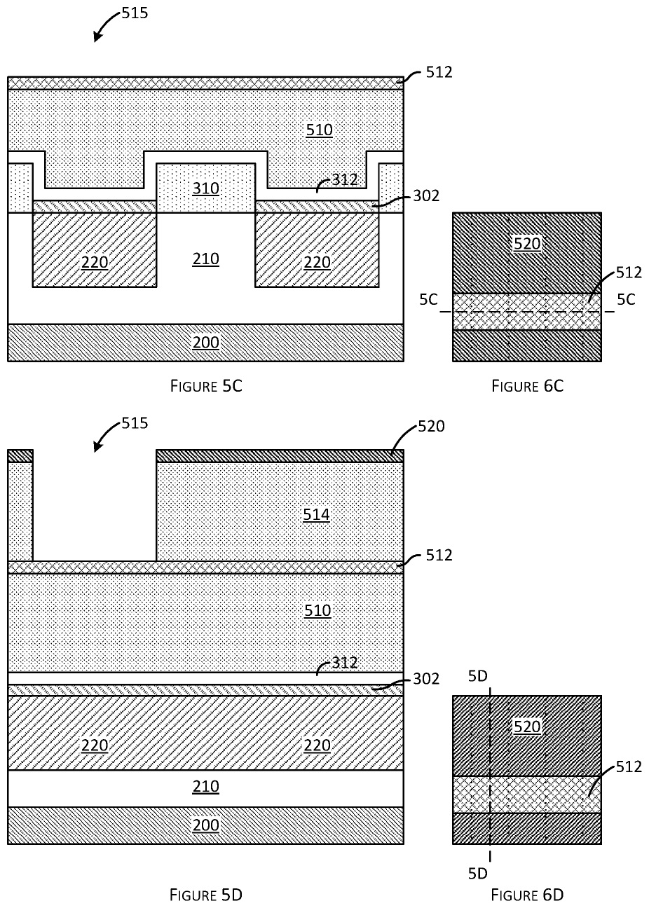

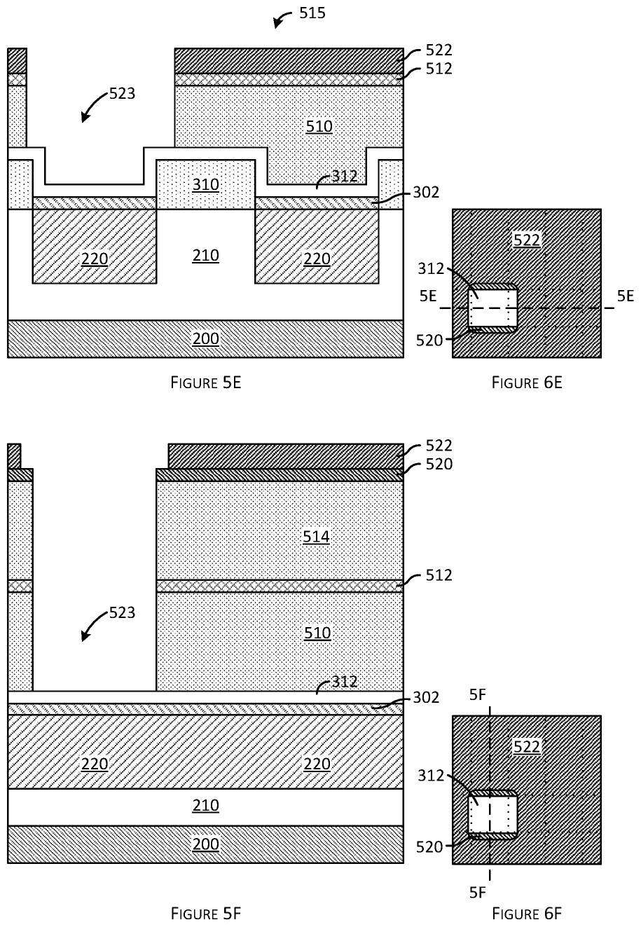

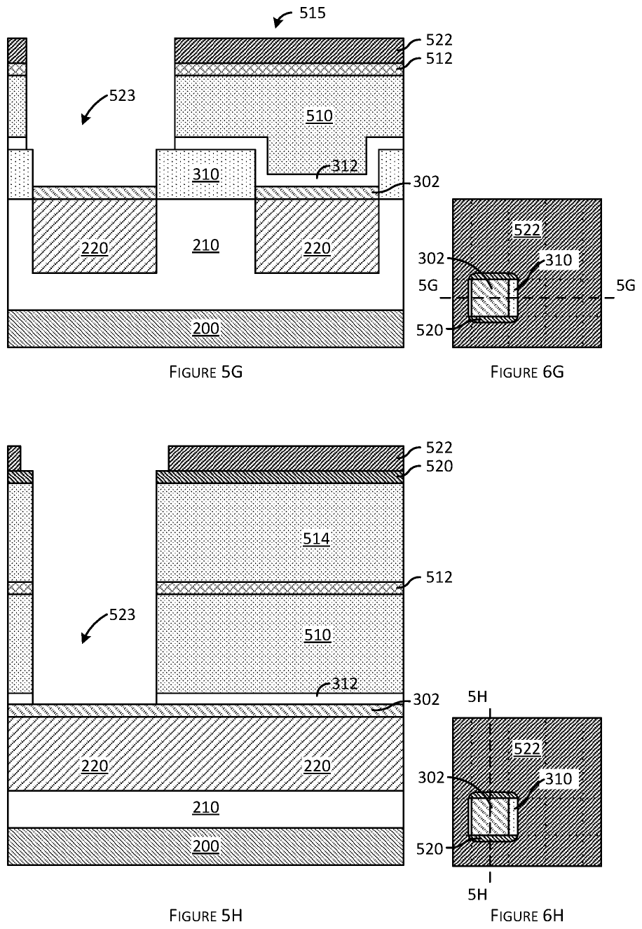

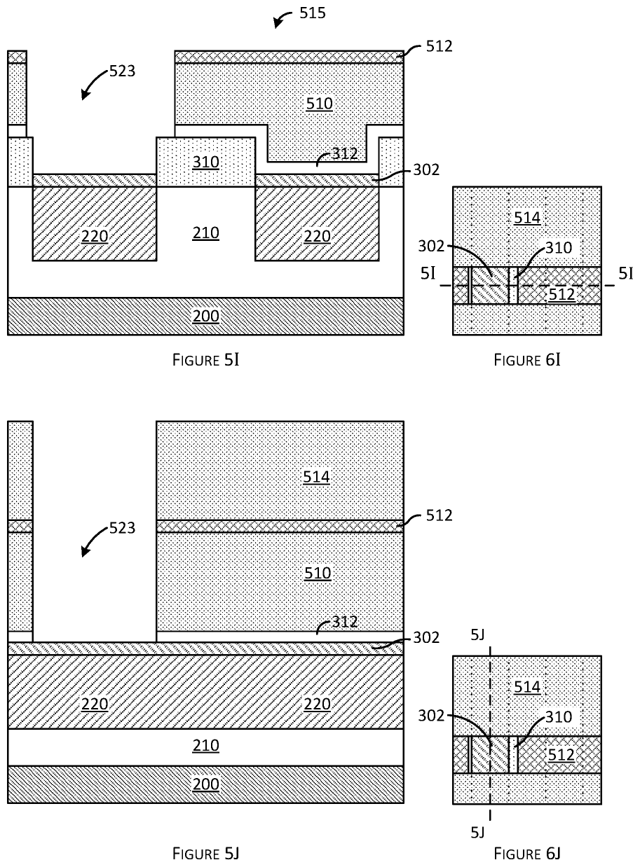

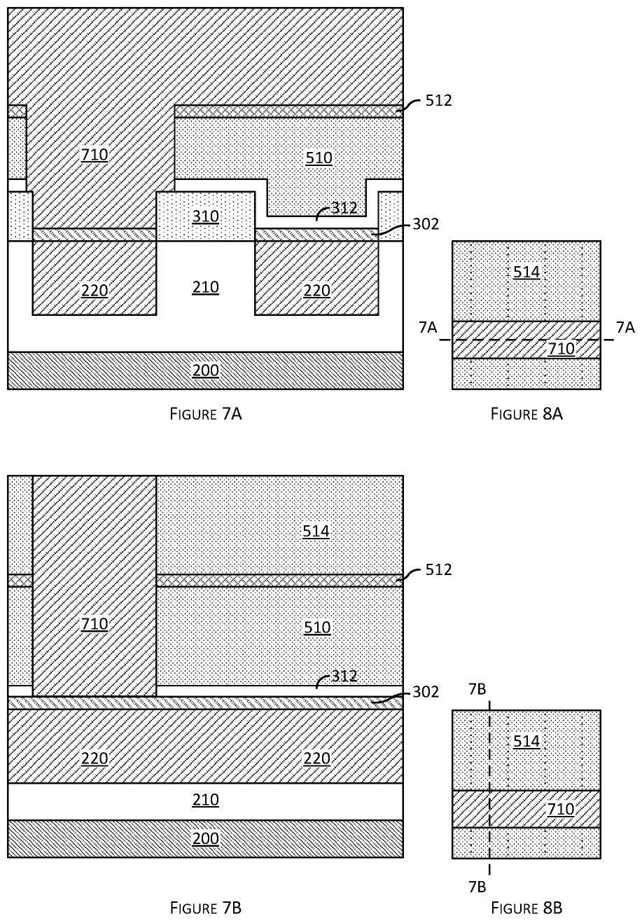

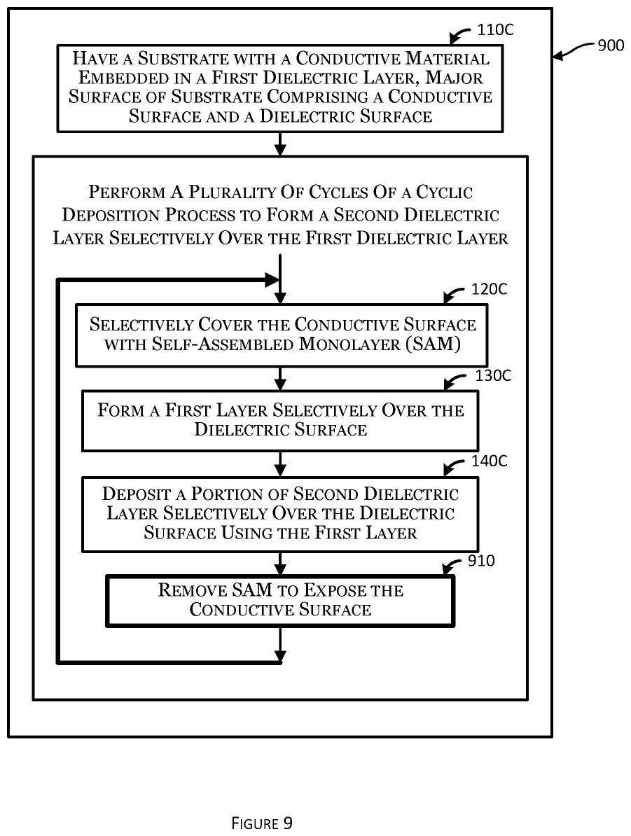

The selective DoD deposition process disclosed herein is described with reference to FIGS. 1A-1B, 2, 3A-3G, and 4A-4G. The process steps involved in forming the various dielectric layers of the ILD layer and in patterning a self-aligned structure in the ILD layer are described with reference to FIGS. 5A-5J and 6A-6J. The FSAV structure, including the conductive lines and the via is illustrated by FIGS. 7A-7B, and 8A-8B. FIG. 9 illustrates a flow diagram to describe implementation of a selective DoD deposition process as a cyclic deposition process where, in each cycle, the conductive and dielectric surfaces are reset, and a new dielectric layer is deposited on the dielectric regions. A plurality of cycles is executed till a target dielectric thickness is achieved.

FIG. 1A illustrates a flow diagram for a selective DoD deposition method 100A in accordance with an embodiment, while FIG. 1B illustrates a flow diagram for a selective DoD deposition method 100B in accordance with an embodiment. A more detailed description is provided below after briefly discussing the flow charts.

Briefly, the selective DoD deposition method 100A of semiconductor processing includes providing a substrate having a major surface comprising a pattern of conductive material embedded in a first dielectric layer (block 110A). The method includes forming a self-assembled monolayer (SAM) selectively over the pattern of conductive material (block 120A). The method includes forming a first layer comprising a first metal selectively over the first dielectric layer (block 130A), where the SAM comprises a tail group that blocks the forming of the first layer (the layer comprising the first metal) over the pattern of conductive material embedded in the first dielectric layer. The method includes depositing a second dielectric layer selectively over the first dielectric layer by performing a catalytic process using the first layer over the first dielectric layer as a source for the catalyst (block 140A).

Briefly, the selective DoD deposition method 100B of processing a semiconductor substrate includes having a substrate comprising a conductive material embedded in a first dielectric layer, where the substrate has a major surface comprising a conductive surface of the conductive material and a dielectric surface of the first dielectric layer (block 110B). The method includes capping the dielectric surface with a metal-containing layer by selectively depositing the metal-containing layer over the dielectric surface (block 130B). The capping of the dielectric surface comprises forming a self-assembled monolayer (SAM) selectively over the conductive surface. The method includes forming a second dielectric layer from the metal-containing layer, the second dielectric layer being selectively deposited over the first dielectric layer (block 140B), where the second dielectric layer is having an upper exposed surface above the conductive surface, after forming the second dielectric layer.

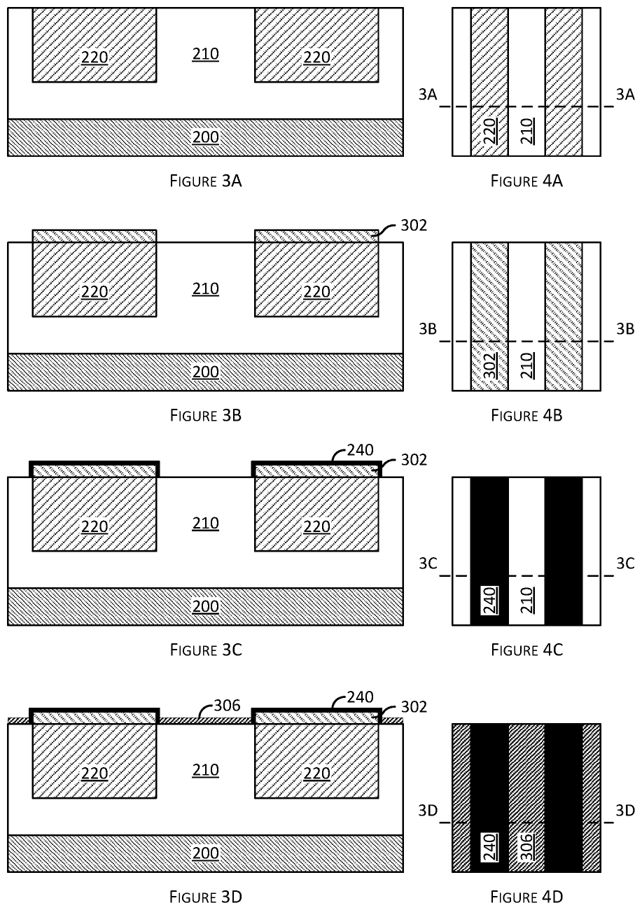

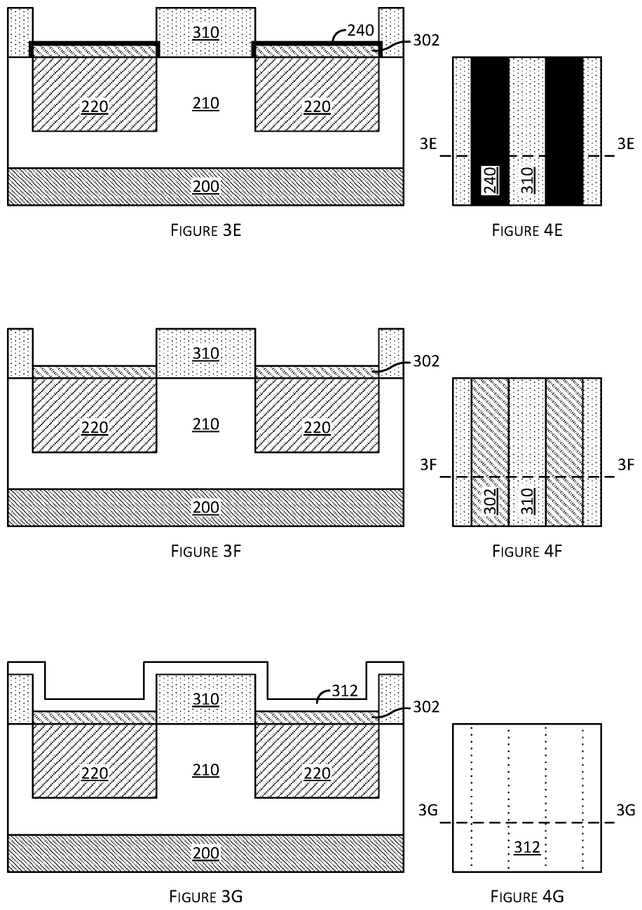

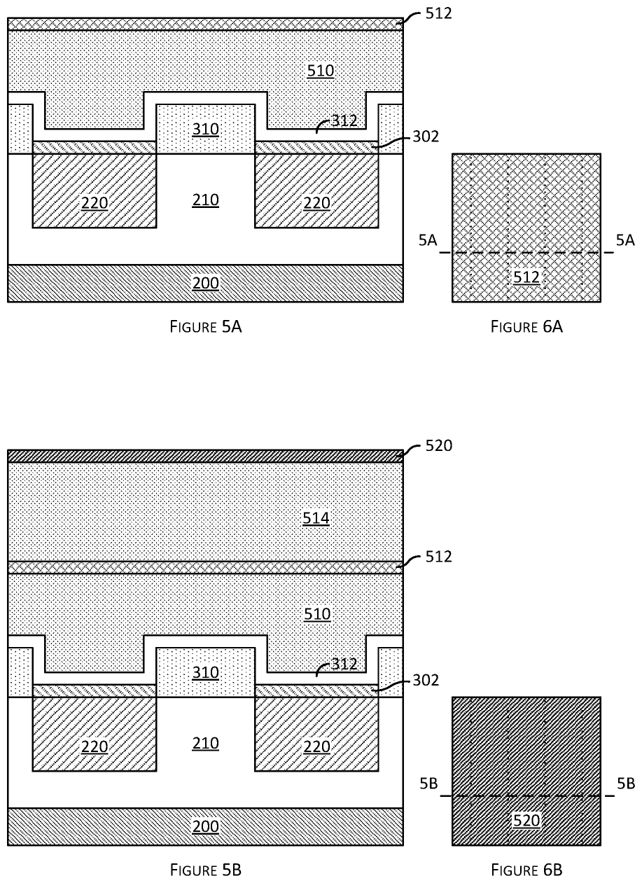

As illustrated in blocks 110A and 110B, the incoming substrate for the selective DoD deposition methods 100A and 100B has a planarized surface comprising conductive and dielectric regions. A cross-sectional view of the incoming substrate in an example of FSAV process flow is illustrated in FIG. 3A, and a planar view of the planarized top surface is illustrated in FIG. 4A. As illustrated in FIGS. 3A and 4A, the top surface comprises an exposed conductive surface of conductive lines 220 embedded in a first dielectric layer 210 having a top dielectric surface substantially coplanar with the conductive surface of the conductive lines 220. The conductive lines 220 may comprise a metal such as copper and may include one or more conductive liners for adhesion as well as to block diffusion of metal into the first dielectric layer 210. The conductive liner material may comprise, for example, titanium, titanium nitride, tantalum, tantalum nitride, or a combination thereof. The first dielectric layer 210, in FIG. 3A, may comprise a low-K dielectric such as fluorosilicate glass (FSG) or carbon-doped silicon oxide (CDO) formed over a substrate layer 200. The first dielectric layer 210 may further comprise one or more etch stop layers, including a CMP etch stop layer. The etch stop layers may comprise aluminum oxide, titanium oxide, silicon nitride, silicon oxynidride, silicon carbonitride, or combinations thereof. In the example FSAV process flow, the conductive elements embedded in an ILD layer of the lower interconnect level comprises the conductive lines 220 embedded in the first dielectric layer 210.

As shown in block 120A in the flow diagram for the selective DoD deposition method 100A and in cross-sectional view in FIG. 2, a self-assembled monolayer (SAM) 240 may be formed selectively over a metal surface by exposing the substrate to a SAM precursor. The SAM 240 in FIG. 2 is a self-limiting chemisorbed layer comprising clusters of molecules distributed roughly uniformly over the surface of the conductive lines 220. As illustrated schematically in FIG. 2, each molecule 230 comprises a reacted head group 232 and a tail group 234, the tail group being an alkyl chain (a hydrocarbon chain with a methyl terminal group), indicated by a zig-zag line labeled by the letter R. The reacted head group 232, in the SAM molecule 230 in FIG. 2, is a ligand such as a thiol (—SH) group that bonds with the metal, thereby anchoring the molecule 230 to the metallic surface of the conductive lines 220. The self-organization is driven by van der Waals forces between the tail groups 234. With time, more head groups 232 assemble on the surface and the respective tail groups 234 assemble above the surface as closely-packed clusters of molecules with a roughly vertical orientation, eventually forming a dense SAM 240. In the selective DoD deposition method 100A, the tail group 234 in the molecules 230 of SAM 240 is used to block a chemical reaction from occurring over the conductive lines 220 during a subsequent area selective deposition (ASD) step used to place a metal-containing layer selectively over the first dielectric layer 210 in FIG. 2, as indicated in block 130A. Similar to the selective DoD deposition method 100A, the selective DoD deposition method 100B also includes selectively forming a metal-containing cap over the first dielectric layer 210, as indicated in block 130B. In the example FSAV process flows described herein, the selective deposition of metal on dielectric may be achieved by using the SAM 240 to block a reaction with the metal precursor used to deposit the metal-containing layer over the first dielectric layer 210, as indicated in blocks 130A and 130B.

In various BEOL process flows, a metallic capping layer may be optionally formed over the surface of the conductive lines of an interconnect level to improve electromigration reliability and suppress void formation in the metal. In some embodiment, the metallic capping layer may be formed prior to forming the SAM while, in some other embodiment, the metallic capping layer is formed subsequent to performing the selective DoD deposition and removing the SAM. FIG. 2 illustrates an embodiment where the SAM 240 has been deposited over the conductive lines 220 without first forming a metallic capping layer and, as described in further detail below, FIG. 3C illustrates an embodiment where the SAM 240 has been deposited after capping the conductive lines 220 with a metallic capping layer 302.

In the example embodiment, illustrated in FIGS. 3B and 4B, a second layer comprising a second metal, e.g., a metallic capping layer 302, has been formed over the surface of the conductive lines 220 prior to forming the SAM 240. A surface treatment, clean, or etch to remove native metal oxide may be performed prior to depositing the metallic capping layer 302. A surface treatment to make the dielectric surface hydrophobic may be optionally performed prior to depositing the capping layer 302. Also, a low-K dielectric repair treatment may be optionally performed prior to depositing the capping layer 302. In one embodiment, the surface may be treated with, for example, (dimethylamino)trimethylsilane (DMATMS) to repair the dielectric and so that the surface of the first dielectric layer 210 is hydrophobic prior to depositing the metallic capping layer 302. The capping layer 302 comprises a second metal such as manganese, a conductive allotrope of carbon (e.g., graphene), ruthenium, molybdenum, copper, titanium, tantalum, tungsten, iridium, platinum, gold, or cobalt and may be formed using a suitable selective metal on metal (MoM) deposition process such as a chemical vapor deposition (CVD), plasma enhanced CVD (PECVD), atomic layer deposition (ALD), or plasma enhanced ALD (PEALD) process with an appropriate metal precursor. The capping layer 302 is generally a conductive layer comprising a metal, but it may comprise other conductive material, for example, carbon.

In one embodiment, where an ALD (or PEALD) process is utilized to form the capping layer 302 comprising ruthenium, an organometallic ruthenium precursor may be used to achieve the desired area selectivity. In another embodiment a CVD process is utilized to form the capping layer 302 comprising ruthenium, a zero valent ruthenium carbonyl precursor may be used to achieve the desired ASD. The capping layer 302 may be deposited using a selective MoM deposition process in which the metallic capping layer 302 is deposited in a self-aligned fashioned on the conductive lines 220, as illustrated in FIGS. 3A and 3B. It will be recognized by one skilled in the art that selective MoM depositions are known for a variety of metal combinations. Rendering the non-growth area, in this case the first dielectric layer 210, hydrophobic generally improves the selectivity of selective MoM depositions.

In FIGS. 3C and 4C, a SAM 240 is formed over the metallic capping layer 302. In the example embodiment, the SAM 240 may be formed by exposing the surface of the substrate to a vapor or liquid comprising a SAM precursor comprising a thiol head group, and a tail group comprising an alkyl chain having a methyl terminal group. For example, the SAM precursor may be dodecanthiol, octanethiol, hexanethiol, or octadecanethiol. A surface treatment, clean, or etch may be performed to remove native metal oxide prior to exposing the substrate to the SAM precursor. In addition, the surface may be treated with, for example, (dimethylamino)trimethylsilane (DMATMS) so that the surface of the first dielectric layer 210 is hydrophobic when the substrate is being exposed to the SAM precursor. In the example embodiment illustrated in FIGS. 3C and 4C, the SAM precursor may be dodecanethiol comprising a non-fluorine containing alkyl chain. Using a SAM with no fluorine content provides the advantage of a reduced adverse environmental impact for the embodiments described in this disclosure.

As indicated in blocks 130A and 130B of the selective DoD deposition methods 100A and 100B and illustrated in FIGS. 3D and 4D, a first layer comprising a first metal, e.g., a metal-containing layer 306 may be selectively deposited over the first dielectric layer 210 by exposing the substrate to a metal precursor. The area selectivity stems from the chemical behavior of the SAM 240. The tail group 234 in the molecules 230 of SAM 240 blocks a chemical reaction with the metal precursor from occurring over the conductive surface to which the SAM 240 is attached. Thus, as illustrated in FIGS. 3D and 4D, the metal-containing layer 306 is formed over the surface of the first dielectric layer 210 selectively. In the example embodiment illustrated in FIGS. 3D and 4D, the metal precursor is an alkylaluminum alkoxide and the tail group of the SAM is an alkyl chain with a methyl terminal group. In one embodiment, the metal-containing layer 306 may comprise less than or equal to a monolayer, for example, about one-third to one monolayer in various embodiments. In another embodiment, the thickness of the metal-containing layer 306 may be about 2 nm, or between about 1 nm to about 3 nm in various embodiments.

In one embodiment, the alkylaluminum alkoxide precursor dimethylaluminum isopropoxide is used to include aluminum ions in the metal-containing layer 306. Use of dimethylaluminum isopropoxide provides several advantages over using an alternative metal precursor gas such as trimethylaluminum (TMA). With dimethylaluminum isopropoxide, a high selectivity ASD process may be achieved without using a fluorinated SAM or precursor to selectively form the metal-containing layer 306 on the first dielectric layer 210. Furthermore, being non-pyrophoric, dimethylaluminum isopropoxide is safer to use in manufacturing. In some other embodiments, some other metal may be used in the metal-containing layer 306. For example, titanium may be included in the metal-containing layer 306 by using a metal precursor such as a titanium amide or titanium tetrachloride.

Blocks 140A and 140B of the selective DoD deposition methods 100A and 100B indicate that a second dielectric layer 310 is formed selectively over the first dielectric layer 210, after forming the metal-containing layer 306. In FIGS. 3E and 4E, the second dielectric layer 310 has been deposited selectively over the first dielectric layer 210. The deposition chemistry includes a catalytic decomposition of a precursor where the metal-containing layer 306 provides the catalyst. For example, the metal-containing layer 306 may comprise aluminum, and the second dielectric layer 310 may comprise silicon oxide formed by a catalytic ALD process that includes decomposition of an alkoxysilanol precursor with aluminum as the catalyst. Because the metal-containing layer 306 has been deposited selectively by blocking the deposition reaction with the SAM 240, the catalyst is available only over the dielectric surface of the substrate. Hence, the second dielectric layer 310 is formed selectively over the first dielectric layer 210.

In various embodiments, the alkoxysilanol precursor may comprise tris(tert-butoxy)silanol, tris(tert-pentoxy)silanol, methyl bis(tert-butoxy)silanol, or methyl bis(tert-pentoxy)silanol. The deposition may be performed at a low pressure of about 0.5 Torr to about 10 Torr, and at an elevated temperature of about 150° C. to about 350° C. In some embodiments, an ALD process comprising a first reaction to decompose an alkoxysilanol precursor with aluminum as catalyst is performed to deposit silicon oxide. About 4 nm to about 6 nm thick silicon oxide film may be deposited in each reaction cycle of the catalytic ALD process. The reaction byproducts such as methane and isopropanol are gases that may be removed from the processing chamber by a vacuum pump.

The selective DoD deposition methods 100A and 100B complete with the selective deposition of the second dielectric layer 310, as seen in the flow diagram in FIGS. 1A and 1B. After the second dielectric layer 310 has been formed, the SAM 240 may be removed by an oxidative etch process. The oxidative etch process may comprise exposing the substrate to an oxidizing agent such as oxygen, ozone, water vapor, or hydrogen peroxide. In the example, FSAV process flow illustrated in FIGS. 3E and 4E, the optional metallic capping layer 302 is formed prior to forming the SAM 240. However, in some other embodiment, the SAM 240 may be formed over the uncapped conductive surface of the conductive lines 220 (e.g., as shown in FIG. 2), and the optional metallic capping layer 302 may be formed after the removal of the SAM 240 is completed.

The upper surface of the substrate, at this stage of the process flow, comprises a dielectric surface comprising a top surface of the second dielectric layer 310, and a conductive surface comprising a top surface of the metallic capping layer 302, as illustrated in FIGS. 3F and 4F. It is noted that the substantially coplanar conductive and dielectric surfaces of the top surface of the incoming substrate (see FIG. 3A) has been modified by the selective DoD deposition methods 100A and 100B to where the upper exposed surface comprises a dielectric surface, the top which is above the conductive surface, as illustrated in FIG. 3F. The step height at the transition between the conductive surface and the dielectric surface may be about 3 nm to about 15 nm, in various embodiments.

In some applications, the process parameters, such as the processing temperature and the target thickness of the second dielectric layer 310, may be such that there is an undesirable loss in area selectivity during the progression of the ASD process. Such degradation in area selectivity, for the example selective DoD deposition process, may be attributed partially to damage to the SAM 240, or pre-existing nucleation sites, or newly generated nucleation sites in the SAM 240. Nucleation sites in the SAM 240 may be caused by various irregularities or defects. The type of irregularity or defect may include, for example, a reactive site on the surface which was not passivated by the SAM 240 due to steric effects, a topology factor such as a micro-cavity or protrusion; impurities such as foreign material trapped in the SAM 240, or other possible defect formation mechanisms. As explained further below with reference to FIG. 9, a cyclic deposition technique may be used in a selective DoD deposition method. The cyclic deposition technique may improve the selectivity of the selective DoD deposition process step relative to the respective non-cyclic processing performed in the selective DoD deposition methods 100A and 100B.

In the example FSAV process flow, a roughly conformal first etch stop layer 312 is formed after the catalytic selective DoD deposition of the second dielectric layer 310 has been completed and the SAM 240 has been removed. The first etch stop layer 312 is covering the upper surface of the substrate, in the example embodiment illustrated in FIGS. 3G and 4G. The purpose of the first etch stop layer 312 is to preserve the second dielectric layer 310 during a subsequent via etch process step. In one embodiment, an optional etch, surface treatment, or clean may be performed prior to the deposition of the first etch stop layer. The purpose of the etch, surface treatment, or clean may be to remove residual SAMs on the surface, to remove metal oxide on the surface, or to provide a better surface for nucleation of the first etch stop layer 312.

In some other embodiment (not shown), a first etch stop layer may be deposited selectively over the second dielectric layer 310 by using a suitable selective DoD deposition process. Such a selectively deposited first etch stop layer would be self-aligned to the dielectric surface of the second dielectric layer 310 disposed on opposite sides of the conductive lines 220 and the metallic capping layer 302.

Irrespective of whether the first etch stop layer is self-aligned to the conductive lines 220 and the metallic capping layer 302, or is covering the entire upper surface (e.g., the first etch stop layer 312 shown in FIGS. 3G and 4G) the structure comprising the first etch stop layer may successfully protect the raised features of the second dielectric layer 310 from being etched during a subsequent via etch process step. The structure thereby enables a via etch to pattern the via openings on the conductive lines of the lower interconnect level, such that the openings are formed self-aligned to the line edges. In the example embodiment, the conductive lines of the lower interconnect level comprise the conductive lines 220 along with the metallic capping layer 302. The self-aligned via opening is described below with reference to the cross-sectional views and planar views illustrated in FIGS. 5G, 6G, 5H, and 6H.

The first etch stop layer 312 may comprise aluminum oxide, titanium oxide, silicon nitride, silicon oxynitride, silicon carbonitride, or combinations thereof.

The remaining steps of the example FSAV process flow, illustrated in FIGS. 5A-5J and 6A-6J, when executed, form a self-aligned via structure where a via opening is formed self-aligned to the line edges of the conductive lines of the upper interconnect level. While a specific self-aligned via process integration method has been described in the example embodiment with reference to the cross-sectional and planar views illustrated in FIGS. 5A-5J and 6A-6J, it is understood that some other suitable self-aligned via process integration method may also be used.

The upper interconnect level is formed by forming conductive elements embedded in an interlayer dielectric (ILD) layer formed over the first etch stop layer 312. As illustrated in FIGS. 5A, 6A, 5B, and 6B, the ILD layer comprises several dielectric layers formed in succession. A first ILD layer 510 may be formed over the first etch stop layer 312, a second etch stop layer 512 may be formed over the first ILD layer 510, and a second ILD layer 514 may be formed over the second etch stop layer 512. The first ILD layer 510 and the second ILD layer 514 may comprise a low-K dielectric such as FSG or CDO. The second ILD layer 514 may include a CMP etch stop capping layer (not shown explicitly) over the low-K dielectric. The CMP etch stop capping layer and the second etch stop layer 512 may comprise aluminum oxide, titanium oxide, silicon nitride, silicon oxynitride, silicon carbonitride, or combinations thereof. As illustrated in FIG. 5B a hard mask layer referred to as the trench hard mask 520 is formed over the second ILD layer 514. The trench hard mask 520 may comprise a stack of layers comprising silicon nitride, silicon oxynitride, silicon carbonitride, titanium nitride, aluminum oxide, ruthenium or combinations thereof.

In FIGS. 5C, 6C, 5D, and 6D, the trench hard mask 520 has been patterned using any suitable photolithography technique (e.g., EUV or i-DUV), and the patterned trench hard mask 520 has been used to etch trenches 515 in the second ILD layer 514 for forming conductive lines of the upper interconnect level. The trench etch removes a region of the second ILD layer 514, stopping on the second etch stop layer 512.

It is typical of conductive lines of an interconnect level to be oriented as parallel lines that are perpendicular to the parallel conductive lines of a vertically adjacent interconnect level. Accordingly, the exposed second etch stop layer 512 at the bottom of the trenches, illustrated in the planar view in FIGS. 6C and 6D, is shown to be perpendicular to the conductive lines 220 of the lower interconnect level (illustrated in the planar view in FIG. 4A); it is understood that a different orientation may be used.

FIGS. 5E, 6E, 5F, and 6F illustrate a patterned via hard mask 522 formed over the trench hard mask 520, and a first via etch performed to create a partially formed via hole 523 in the ILD extending down to the first etch stop layer 312. It is noted that the via hard mask 522 is formed over the trench hard mask 520 and over the exposed regions of the second etch stop layer 512 at the bottom of the trenches 515. The material selected for the via hard mask 522 is such that the etch chemistry used to pattern the via hard mask 522 does not substantially remove any region of the trench hard mask 520 that may be exposed during the removal of the material of the via hard mask 522. For example, the trench hard mask 520 may comprise silicon nitride and the via hard mask 522 may comprise titanium nitride. Or, the trench hard mask 520 may comprise titanium nitride and the via hard mask 522 may comprise silicon carbonitride. A via hard mask etch may then use, for example, reactive ion etching using a fluorocarbon chemistry to remove exposed regions of the via hard mask 522 selective to the trench hard mask 520 and the other exposed dielectric layers.

As explained above, the first via etch is performed using the combined trench hard mask 520 and via hard mask 522 as the masking layer. The presence of the patterned trench hard mask 520 during the first via etch is responsible for forming the via hole 523 in the ILD layers self-aligned to the trenches 515. Here, the ILD layers refer to the second ILD layer 514, the second etch stop layer 512, and the first ILD layer 510. A suitable etch technique such as anisotropic reactive ion etching (RIE) comprising one or more steps having different etch chemistries may be used to form the partially formed via hole 523.

The second via etch removes the exposed regions of the first etch stop layer 312 and extends the via hole 523 to expose a top conductive surface (e.g., the surface of the metallic capping layer 302), as illustrated in FIGS. 5G, 6G, 5H, and 6H. The etch chemistry of the second via etch process removes the first etch stop layer 312 selective to the second dielectric layer 310 and stop on the conductive surface (e.g., the surface of the metallic capping layer 302) adjacent below the first etch stop layer 312. Accordingly, as illustrated in FIGS. 5G and 5H, the via hole 523 is fully self-aligned.

After the processing used to form the via hole 523 has been completed, the via hard mask 522 and the trench hard mask 520 may be removed using a suitable wet or dry etch process or a combination of several etch process steps, as illustrated in FIGS. 5I, 6I, 5J, and 6J.

Next, the fully self-aligned via holes 523 and the trenches 515 are filled with conductive material deposited over the upper surface of the substrate and damascened to remove excess conductive material and form the conductive lines and vias of the upper interconnect level inlaid in the ILD layer. The damascene etch may be, for example, a metal CMP process. The CMP etch may stop on the CMP etch stop layer of the second ILD layer 514. The final structure after the damascene etch has been completed is illustrated in FIGS. 7A, 8A, 7B, and 8B. The deposited and damascened conductive layer 710 may comprise various conductive layers such as adhesion liners, diffusion barriers, and metal fill materials. For example, the liner materials and diffusion barriers may comprise titanium, titanium nitride, tantalum, tantalum nitride, ruthenium, cobalt, and the like. The metal fill material may be aluminum, copper, ruthenium, cobalt, and the like. Various deposition techniques may be used to completely fill the high aspect ratio openings, for example, PECVD, electroplating, ALD, PEALD, and bottom-up processing using, for example, an area selective deposition technique. Sufficient conductive material is deposited to ensure that, prior to the damascene etch using CMP, the lowermost level of the top surface of the conductive layer 710 is formed above the uppermost level of the upper surface of the substrate below the conductive layer 710. For example, the top of the second ILD layer 514 is below the lowest point in the conductive layer 710.

FIGS. 7A and 7B illustrate cross-sectional views of the via structure after the metal CMP is complete. It is noted that the via illustrated in FIGS. 7A and 7B is formed fully self-aligned: The via is self-aligned to a conductive line of the lower the interconnect level and to a conductive line of the upper interconnect level.

FIG. 9 illustrates a flow diagram for a cyclic selective DoD deposition method 900 wherein, the selective DoD deposition process is performed using a cyclic deposition technique. The method includes having a substrate comprising a conductive material embedded in a first dielectric layer (block 110C), where the substrate has a major surface comprising a conductive surface of the conductive material and a dielectric surface of the first dielectric layer. The method further includes performing a plurality of cycles of a cyclic deposition process to form a second dielectric layer selectively over the first dielectric layer. Each cycle of the cyclic deposition process includes selectively covering the conductive surface with a self-assembled monolayer (SAM) (block 120C). A metal-containing layer is formed selectively over the dielectric surface, where the SAM comprises a tail group that blocks the forming of the metal-containing layer on the conductive surface (block 130C). A portion of the second dielectric layer is deposited selectively over the dielectric surface by performing a catalytic process using the metal-containing layer as the catalyst (block 140C), where the deposited portion of the second dielectric having an exposed dielectric surface above the conductive surface. The individual process steps in blocks 110C, 120C, 130C, and 140C may use the same processing techniques described above, for example, the techniques used to execute the blocks 110A, 120A, 130A, and 140A for the selective DoD deposition method 100A. However, as indicated in block 910 in FIG. 9, before the second dielectric layer 310 has been formed completely up to the target thickness, the dielectric deposition is interrupted and the upper surface is reset by removing the SAM to again expose the conductive surface below the SAM (block 910).

In the next cycle, a new SAM is formed over the conductive surface (block 120C), thereby resetting the conductive surface. After forming the new SAM, the dielectric surface is reset in each cycle by selectively forming a new metal-containing layer over the exposed dielectric surface (block 130C). The area selectivity of the deposition process used in forming the new metal-containing layer may be achieved by using the new SAM to block the deposition reaction over the conductive lines of the lower interconnect level, as described above for the selective DoD deposition methods 100A and 100B. Next, one or more reaction cycles of the catalytic ALD process (described above for the selective DoD deposition methods 100A and 100B) may be performed to deposit more of the second dielectric material selectively over the dielectric surface. As before, the area selectivity is achieved by the selective presence of the catalyst (provided by the new metal-containing layer) over the dielectric surface. Resetting the surface with a new SAM and a new metal-containing layer cures the degradation in area selectivity during processing (explained above), and provides the advantage higher selectivity.

In the cyclic selective DoD deposition method 900, described above, both the conductive surface and the dielectric surface is reset in each cycle by forming the new SAM and the new metal-containing layer, respectively. However, it is understood that, in some embodiments, it may be optional to form a new metal-containing layer in every cycle of the cyclic selective DoD deposition process while only forming a new SAM layer in one or a few of the DOD cycles.

Example 1. A method of processing a semiconductor substrate, the method includes having a substrate including a conductive material embedded in a first dielectric layer, the substrate having a major surface including a conductive surface of the conductive material and a dielectric surface of the first dielectric layer; capping the dielectric surface with a metal-containing layer by selectively depositing the metal-containing layer over the dielectric surface; and forming a second dielectric layer from the metal-containing layer, the second dielectric layer being selectively deposited over the first dielectric layer, the second dielectric layer having an upper exposed surface above the conductive surface after forming the second dielectric layer.

Example 2. The method of example 1, where the metal-containing layer includes aluminum or titanium.

Example 3. The method of one of examples 1 or 2, where capping the dielectric surface with the metal-containing layer includes forming a self-assembled monolayer (SAM) selectively over the conductive surface, the SAM including an alkyl tail group that blocks chemical reaction with an alkylaluminum alkoxide precursor.

Example 4. The method of one of examples 1 to 3, where capping the dielectric surface with the metal-containing layer includes: forming a self-assembled monolayer (SAM) selectively over the conductive surface, the SAM includes a tail group that is an alkyl chain having a methyl terminal group, and depositing aluminum selectively over the first dielectric layer by a chemical reaction with an alkylaluminum alkoxide precursor, the chemical reaction being selectively blocked over the conductive surface by the SAM; and where forming the second dielectric layer from the metal-containing layer includes: selectively depositing the second dielectric layer over the first dielectric layer by using the aluminum over the dielectric surface for a catalytic atomic layer deposition (ALD) of silicon oxide, and removing the SAM after depositing the second dielectric layer.

Example 5. The method of one of examples 1 to 4, further including forming a metallic capping layer selectively over the conductive material by a selective deposition of metal.

Example 6. The method of one of examples 1 to 5, where the metallic capping layer includes ruthenium, molybdenum, manganese, conductive allotrope of carbon, copper, titanium, tantalum, tungsten, iridium, platinum, gold, or cobalt.

Example 7. The method of one of examples 1 to 6, further including: forming a first etch stop layer over the upper exposed surface after forming the second dielectric layer; forming an interlayer dielectric layer over the first etch stop layer; and forming a via through the interlayer dielectric layer and the first etch stop layer to contact the conductive material using a self-aligned via process.

Example 8. A method of semiconductor processing including: providing a substrate having a major surface including a pattern of conductive material embedded in a first dielectric layer; forming a self-assembled monolayer (SAM) selectively over the pattern of conductive material; forming a first layer including a first metal selectively over the first dielectric layer, the SAM including a tail group that blocks the forming of the first layer over the pattern of conductive material; and depositing a second dielectric layer selectively over the first dielectric layer by performing a catalytic process using the first layer over the first dielectric layer.

Example 9. The method of example 8, where forming the first layer over the first dielectric layer includes exposing a major surface of the first dielectric layer and the SAM to a metal precursor, the SAM including a thiol head group and a non-fluorinated alkyl tail group.

Example 10. The method of one of examples 8 or 9, where the metal precursor includes an alkylaluminum alkoxide precursor, and where the SAM includes a non-fluorinated alkyl tail group or where the metal precursor includes titanium and the SAM includes a non-fluorinated alkyl tail group.

Example 11. The method of one of examples 8 to 10, where the alkylaluminum alkoxide precursor includes dimethylaluminum isopropoxide.

Example 12. The method of one of examples 8 to 11, further including selectively forming a second layer capping the conductive material, and where the second layer includes ruthenium, molybdenum, manganese, conductive allotrope of carbon, copper, titanium, tantalum, tungsten, iridium, platinum, gold, or cobalt.

Example 13. The method of one of examples 8 to 12, further including performing a surface treatment prior to forming the second layer, the surface of the first dielectric being hydrophobic after the surface treatment is completed.

Example 14. The method of one of examples 8 to 13, where performing the surface treatment includes treating the surface with (dimethylamino) trimethylsilane (DMATMS).

Example 15. The method of one of examples 8 to 14, where depositing the second dielectric layer includes depositing a silicon oxide layer selectively over the first dielectric layer by performing a catalytic atomic layer deposition (ALD) process using the first layer in a reaction with an alkoxysilanol precursor.

Example 16. The method of one of examples 8 to 15, where the alkoxysilanol precursor includes tris(tert-butoxy)silanol, tris(tert-pentoxy)silanol, methyl bis(tert-butoxy)silanol, or methyl bis(tert-pentoxy)silanol.

Example 17. A method of semiconductor processing, the method including: having a substrate including a conductive material embedded in a first dielectric layer, the substrate having a major surface including a conductive surface of the conductive material and a dielectric surface of the first dielectric layer; performing a plurality of cycles of a cyclic deposition process to form a second dielectric layer selectively over the first dielectric layer, each cycle of the cyclic deposition process including: selectively covering the conductive surface with a self-assembled monolayer (SAM); forming a first layer including a first metal selectively over the dielectric surface, the SAM including a tail group that blocks the forming of the first layer on the conductive surface; depositing a portion of the second dielectric layer selectively over the dielectric surface by performing a catalytic process using the first layer, the deposited portion of the second dielectric having an exposed dielectric surface above the conductive surface; and removing the SAM to expose the conductive surface.

Example 18. The method of example 17, where the first layer includes aluminum or titanium.

Example 19. The method of one of examples 17 or 18, where forming the first layer includes exposing the substrate to a vapor including an alkylaluminum alkoxide precursor, the SAM including a thiol head group and a non-fluorinated alkyl tail group that blocks chemical reaction with the alkylaluminum alkoxide precursor; and where depositing the portion of the second dielectric layer includes depositing a silicon oxide layer selectively over the dielectric surface by performing a catalytic atomic layer deposition (ALD) process using the first layer in a reaction with an alkoxysilanol precursor.

Example 20. The method of one of examples 0 to 19, where the alkylaluminum alkoxide precursor includes dimethylaluminum isopropoxide.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of processing a semiconductor substrate, the method comprising:
having a substrate comprising a conductive material embedded in a first dielectric layer, the substrate having a major surface comprising a conductive surface of the conductive material and a dielectric surface of the first dielectric layer;
capping the dielectric surface with a metal-containing layer by selectively depositing the metal-containing layer over the dielectric surface; and
forming a second dielectric layer from the metal-containing layer, the second dielectric layer being selectively deposited over the first dielectric layer, the second dielectric layer having an upper exposed surface above the conductive surface after forming the second dielectric layer.

2. The method of claim 1, wherein the metal-containing layer comprises aluminum or titanium.

3. The method of claim 1, wherein capping the dielectric surface with the metal-containing layer comprises forming a self-assembled monolayer (SAM) selectively over the conductive surface, the SAM comprising an alkyl tail group that blocks chemical reaction with an alkylaluminum alkoxide precursor.

4. The method of claim 1, wherein capping the dielectric surface with the metal-containing layer comprises:
forming a self-assembled monolayer (SAM) selectively over the conductive surface, the SAM comprising a tail group comprising an alkyl chain having a methyl terminal group, and
depositing aluminum selectively over the first dielectric layer by a chemical reaction with an alkylaluminum alkoxide precursor, the chemical reaction being selectively blocked over the conductive surface by the SAM; and
wherein forming the second dielectric layer from the metal-containing layer comprises:
selectively depositing the second dielectric layer over the first dielectric layer by using the aluminum over the dielectric surface for a catalytic atomic layer deposition (ALD) of silicon oxide, and
removing the SAM after depositing the second dielectric layer.

5. The method of claim 1, further comprising forming a metallic capping layer selectively over the conductive material by a selective deposition of metal.

6. The method of claim 5, wherein the metallic capping layer comprises ruthenium, molybdenum, manganese, conductive allotrope of carbon, copper, titanium, tantalum, tungsten, iridium, platinum, gold, or cobalt.

7. The method of claim 1, further comprising:
forming a first etch stop layer over the upper exposed surface after forming the second dielectric layer;
forming an interlayer dielectric layer over the first etch stop layer; and
forming a via through the interlayer dielectric layer and the first etch stop layer to contact the conductive material using a self-aligned via process.

8. A method of semiconductor processing comprising:
providing a substrate having a major surface comprising a pattern of conductive material embedded in a first dielectric layer;
forming a self-assembled monolayer (SAM) selectively over the pattern of conductive material;
forming a first layer comprising a first metal selectively over the first dielectric layer, the SAM comprising a tail group that blocks the forming of the first layer over the pattern of conductive material; and
depositing a second dielectric layer selectively over the first dielectric layer by performing a catalytic process using the first layer over the first dielectric layer.

9. The method of claim 8, wherein forming the first layer over the first dielectric layer comprises exposing a major surface of the first dielectric layer and the SAM to a metal precursor, the SAM comprising a thiol head group and a non-fluorinated alkyl tail group.

10. The method of claim 9, wherein the metal precursor comprises an alkylaluminum alkoxide precursor, and wherein the SAM comprises a non-fluorinated alkyl tail group or wherein the metal precursor comprises titanium and the SAM comprises a non-fluorinated alkyl tail group.

11. The method of claim 10, wherein the alkylaluminum alkoxide precursor comprises dimethylaluminum isopropoxide.

12. The method of claim 8, further comprising selectively forming a second layer capping the conductive material, and wherein the second layer comprises ruthenium, molybdenum, manganese, conductive allotrope of carbon, copper, titanium, tantalum, tungsten, iridium, platinum, gold, or cobalt.

13. The method of claim 12, further comprising performing a surface treatment prior to forming the second layer, the surface of the first dielectric being hydrophobic after the surface treatment is completed.

14. The method of claim 13, wherein performing the surface treatment comprises treating the surface with (dimethylamino) trimethylsilane (DMATMS).

15. The method of claim 8, wherein depositing the second dielectric layer comprises depositing a silicon oxide layer selectively over the first dielectric layer by performing a catalytic atomic layer deposition (ALD) process using the first layer in a reaction with an alkoxysilanol precursor.

16. The method of claim 15, wherein the alkoxysilanol precursor comprises tris(tert-butoxy)silanol, tris(tert-pentoxy)silanol, methyl bis(tert-butoxy)silanol, or methyl bis(tert-pentoxy)silanol.

17. A method of semiconductor processing, the method comprising:
having a substrate comprising a conductive material embedded in a first dielectric layer, the substrate having a major surface comprising a conductive surface of the conductive material and a dielectric surface of the first dielectric layer;
performing a plurality of cycles of a cyclic deposition process to form a second dielectric layer selectively over the first dielectric layer, each cycle of the cyclic deposition process comprising:
selectively covering the conductive surface with a self-assembled monolayer (SAM);
forming a first layer comprising a first metal selectively over the dielectric surface, the SAM comprising a tail group that blocks the forming of the first layer on the conductive surface;
depositing a portion of the second dielectric layer selectively over the dielectric surface by performing a catalytic process using the first layer, the deposited portion of the second dielectric having an exposed dielectric surface above the conductive surface; and
removing the SAM to expose the conductive surface.

18. The method of claim 17, wherein the first layer comprises aluminum or titanium.

19. The method of claim 17,
wherein forming the first layer comprises exposing the substrate to a vapor comprising an alkylaluminum alkoxide precursor, the SAM comprising a thiol head group and a non-fluorinated alkyl tail group that blocks chemical reaction with the alkylaluminum alkoxide precursor; and
wherein depositing the portion of the second dielectric layer comprises depositing a silicon oxide layer selectively over the dielectric surface by performing a catalytic atomic layer deposition (ALD) process using the first layer in a reaction with an alkoxysilanol precursor.

20. The method of claim 20, wherein the alkylaluminum alkoxide precursor comprises dimethylaluminum isopropoxide.
